(19) United States
(12) Patent Application Publication
(10) Pub. No.: US 2014/0311550 A1
(43) Pub. Date: Oct. 23, 2014

(54) LOW WIND RESISTANCE SELF BALLASTING PHOTOVOLTAIC MODULE MOUNTING SYSTEMS

(71) Applicant: NUVOSUN, INC., Milpitas, CA (US)

(72) Inventor: David B. Pearce, Saratoga, CA (US)

(21) Appl. No.: 14/362,282

(22) PCT Filed: Dec. 6, 2012
(86) PCT No.: PCT/US2012/068309

§ 371 Date: Jun. 2, 2014

Related U.S. Application Data
(60) Provisional application No. 61/568,142, filed on Dec. 7, 2011.

(51) Int. Cl. H01L 31/052; H01L 31/042

(52) U.S. Cl. CPC H01L 31/0522; H01L 31/0422
USPC 136/246

(57) ABSTRACT

This disclosure provides a photovoltaic module array mounting system comprising a photovoltaic module array comprising a plurality of photovoltaic modules. An individual photovoltaic module of the plurality can include one or more photovoltaic cells that can be configured to generate electricity upon exposure to light. The system can further comprise a first mounting structure comprising a frame that mounts the photovoltaic module array. The first mounting structure can permit rotation of an individual photovoltaic module of the plurality of photovoltaic modules of the photovoltaic module array. The system can further comprise a second mounting structure mounted to the first mounting structure with the aid of a plurality of posts. The second mounting structure comprises modular elements that are configured to couple to one another with the aid of snap-in feature

### CROSS-REFERENCE

This application claims the benefit of U.S. Provisional Application No. 61/568,142 (“LOW WIND RESISTANCE SELF BALLASTING SOLAR MODULE MOUNTING SYSTEM”), filed Dec. 7, 2011, which application is entirely incorporated herein by reference.

### BACKGROUND

The majority of photovoltaic (PV) modules used on rooftop mounted systems utilize crystalline or polycrystalline silicon cells packaged with a low iron tempered glass top sheet, a TPE (Tedlar®, polyester, EVA) back sheet, an extruded aluminum frame, and a junction box with cables to connect to adjacent modules. The modules are mounted to a metal support structure which is held to the roof with roof penetrating screws, which is undesirable due to the high risk of potential water leaks. Ground mounted utility scale PV modules frequently use a second glass sheet on the back without a frame because it is more economical, and because weight is less of an issue than for roof mounted systems. The glass-glass design has been pioneered by First Solar for their CdTe thin film solar modules, and it has been adopted by some of the manufacturers of copper indium gallium diselenide (CIGS) and amorphous silicon solar cells. Thin film solar cells deposited on glass substrates may require a top sheet of glass to finish the module, and therefore the extra weight makes it problematic to use these in roof mounted arrays. However, thin film cells deposited on thin flexible substrates can use a standard silicon module packaging scheme with the addition of a thin metal foil moisture barrier to the TPE back sheet. Therefore they are more suitable for rooftop installation due to their lighter weight.

Current mounting systems for solar arrays are generally expensive and contribute a large amount of additional weight to a roof mounted system. Part of the reason for this is the extra support needed to deal with large wind loads that can occur over extended areas of densely packed modules. Solyndra has developed a module that consists of tubular light collection elements mounted along a frame somewhat like the rungs of a ladder. A light colored or white roof is relied upon to reflect light that passes through the open spaces back to the tubular elements to improve the overall efficiency. Since the design presents little cross section to wind loading, the normal mounting structure and roof penetrations are eliminated and the modules can be simply placed on the roof and electrically interconnected, thus saving some of the installation costs. However, some area efficiency is lost due to (in time) soiled and less reflective roof surfaces, and the fact that the reflected light can be only partially recollected.

Stationary solar arrays generally are mounted in one of two ways. Either they are mounted in a flat dense packed array on a flat surface (a roof or the ground) or they are mounted at an appropriate angle to more effectively face the average position of the sun over the year. For a roof that happens to have an expanse of southern slope, the array can be mounted almost flat against the roof, but this situation does not arise in many cases. FIG. 1 shows an edge-on view of the typical manner in which a solar array located at a mid northern latitude of 35 degrees may be mounted on flat ground or on a flat roof (for example, large commercial buildings in particular). It consists of rows of modules 1 mounted facing due south at an angle of 35 degrees to receive the most solar flux averaged over the year between the highest summer and lowest winter sun positions. The mounting angle is of course equal to the latitude of the array's location as indicated. In this example the spacing D between the modules is about twice the height H of the module. For this geometry, the maximum shading S that occurs at the lowest winter sun position does not cover any of the next modules, and practically all of the sunlight available to the array area falls on the modules at this time.

At other latitudes, slight changes in spacing and angle are made to minimize shading in a similar way. At the higher sun positions, the shaded area becomes smaller and a significant fraction of the available solar radiation falls between the modules and is lost. This would of course not happen for a dense packed flat array, but such an array is more expensive and does not offer much coverage improvement over the angled array during the low sun periods. If land is cheap (such as, e.g., in the case of a desert) or the flat roof is relatively large, a given size of array can have rows separated enough to avoid shading and gain the extra energy provided by a better average sun facing orientation. However, angled arrays cost more for mounting hardware, are more prone to high wind damage, and suffer from some lost solar collection area at the higher sun angles.

### SUMMARY

In view of the limitations of mounting systems currently available, recognized herein is the need for a more economical mounting system that, for example, avoids roof penetrations, provides lower wind loading, and minimizes high sun angle solar collection loss(es).

This disclosure provides systems and methods for the construction and installation of solar photovoltaic module arrays for the production of solar electricity.

The disclosure provides a low wind resistance system that avoids roof penetrations by providing an economical, integrated, self ballasting support structure. The system may also be used for ground mounted arrays.

An aspect of the disclosure provides a solar module array mounting system that is economical and requires reduced labor to assemble.

Another aspect of the disclosure provides a solar module array roof mounting system that requires no penetrations of the roof.

An additional aspect of the disclosure provides a solar module array mounting system that greatly reduces the wind loading on a given array area.

Yet another aspect of the disclosure provides a solar module array mounting system that reduces high sun angle collection losses.

An aspect of the disclosure provides a photovoltaic module array mounting system, comprising a photovoltaic module array comprising a plurality of photovoltaic modules. An individual photovoltaic module of the plurality can comprise one or more photovoltaic cells, each of which can be configured to generate electricity upon exposure to light. The mounting system can further comprise a first mounting structure comprising a frame that mounts the photovoltaic module array. The first mounting structure can permit rotation of an individual photovoltaic module of the plurality of photovoltaic modules of the photovoltaic module array. The mounting system can further comprise a second mounting structure mounted to the first mounting structure with the aid of a plurality of posts. The second mounting structure can comprise modular elements that are configured to couple to one another with the aid of snap-in features.

Another aspect of the disclosure provides a system for supporting a photovoltaic module array, comprising a photovoltaic module array comprising a plurality of photovoltaic modules. An individual module of the plurality of photovoltaic modules can comprise one or more photovoltaic cells for generating electricity upon exposure to electromagnetic radiation. The system can further comprise a mounting structure disposed adjacent to the photovoltaic module array. The mounting structure can support the plurality of photovoltaic modules at a given angle with respect to the mounting structure. An individual photovoltaic module of the plurality of photovoltaic modules can be rotatably mounted to the mounting structure and be held in position by a support member mounted to the individual photovoltaic module and a channel in the mounting structure. At least two individual photovoltaic modules of the plurality of photovoltaic modules can be adapted to rest parallel to the mounting structure.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “FIG.” and “FIGs.” herein), of which:

FIG. 1 is an edge-on schematic view of a mounting of a photovoltaic (or solar) array at a latitude of 35 degrees north.

FIG. 2 is a perspective view of a substructure A of a solar array mounted in a frame appropriate for assembly in a factory.

FIG. 3 is a schematic view of molded parts of an array mounting system for substructure B.

FIG. 4 is a planar view of assembled parts which form substructure B.

FIG. 5 is a planar view of multiple substructure B elements interconnected into a large area array mounting format.

FIG. 6 is a side view of a part of an array showing substructure A mounted on substructure B.

FIG. 7 is a schematic side view of a “Series K” metal joist and a photograph illustrating the use of joists in a roofing structure.

FIG. 8 is a planar view of a ground mounting structure for a solar array using “Series K” or similar metal joists with interconnecting cross beams.

FIG. 9 is a partial planar view of part of the ground mounting structure of FIG. 8, showing solar module arrays mounted on a metal joist and interconnecting beam structure.

### DETAILED DESCRIPTION

While preferable embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein can be employed in practicing the invention.

The terms “photovoltaic cell” (also “solar cell” herein), as used herein, generally refers to a device comprising a photovoltaic device comprising a photoactive material (or absorber) that is configured to generate electrons and holes (or electricity) upon exposure of the device to electromagnetic radiation (or energy), or a given wavelength or distribution of wavelengths of electromagnetic radiation. A photovoltaic device can include a substrate adjacent to the photoactive material. Examples of photoactive materials include, without limitation, amorphous silicon, copper indium gallium diselenide (CIGS), cadmium telluride (CdTe) and CdZnTe/CdTe.

The term “photovoltaic module,” as used herein, generally refers to a device comprising one or more photovoltaic cells.

Mounting Systems

This disclosure provides a photovoltaic mounting system comprising a first support member for supporting one or more photovoltaic modules that is coupled to a second support member that is configured to rest adjacent to a support surface, or coupled to a support structure. The second support member can be modular.

In some embodiments, a system for supporting a photovoltaic module array comprises a photovoltaic (or solar) module array comprising a plurality of photovoltaic (or solar) modules. An individual module of the plurality of photovoltaic modules comprises one or more photovoltaic cells for generating electricity upon exposure to electromagnetic radiation. An individual module can include at least 1, 2, 3, 4, 5, 6, 7, 8, 9, 10, 20, 30, 40, 50, 60, 70, 80, 90, 100, or 1000 photovoltaic cells. The system further comprises a mounting structure disposed adjacent to the photovoltaic module array. The mounting structure supports the plurality of photovoltaic modules at a given angle with respect to the mounting structure. An individual photovoltaic module of the plurality of photovoltaic modules is rotatably mounted to the mounting structure and is held in position by a support member mounted to the individual photovoltaic module and a channel in the mounting structure. In some cases, at least two individual photovoltaic modules of the plurality of photovoltaic modules are adapted to rest parallel to the mounting structure.

The mounting structure can have various shapes, sizes and configurations. In some cases, the mounting structure is circular, triangular, square, rectangular, pentagonal, hexagonal, heptagonal, octagonal, or nonagonal, or partial shapes or combinations thereof.

In some cases, the at least two individual photovoltaic modules are adapted to rest parallel to the mounting structure without overlapping one another. That is, when both photovoltaic modules rest parallel to the mounting structure, they do not overlap each other. Upon exposure of the modules to light, such configuration can permit shading losses to be minimized.

The at least two individual photovoltaic modules can fold flat into the mounting structure to reduce wind loading. Such configuration can enable wind loading to be reduced by at least 1%, 2%, 3%, 4%, 5%, 10%, 20%, 30%, 40%, 50%, 60%, 70%, 80%, 90%, or 95%. An angle of a photovoltaic module in relation to the general direction of oncoming wind can be changed to reduce or minimize wind loading. In some cases, a control system is provided coupled to a wind speed sensor and a motor that adjusts an angle of a photovoltaic module. The control system measures wind speed using the wind speed sensor and, using the motor, adjusts the angle of the photovoltaic module to reduce or minimize wind loading. Wind loading can be measured, for example, with the aid of a vibration sensor on a frame of the photovoltaic module, or using a table that correlates photovoltaic module angle and wind loading with wind velocity.

The angle of the photovoltaic module can be changed separately from an angle of other photovoltaic modules in the array. Alternatively, the angle of the photovoltaic modules can be changed simultaneously.

In some cases, the system further comprises an optically reflective structure mounted to the mounting structure and in-between the at least two individual photovoltaic modules. The optically reflective structure directs at least a portion of incident electromagnetic radiation onto one the at least two individual photovoltaic modules. In some examples, the optically reflective structure is a mirror. As an alternative, the optically reflective structure is a solar concentrator, such as a concave or hemispherical solar concentrator.

In some cases, the optically reflective structure can be adapted to direct oncoming wind along a direction that is angled with respect to a plane of the mounting structure. The optically reflective structure can direct wind at an angle of at least about 1°, 2°, 3°, 4°, 5°, 10°, 20°, 30°, 40°, 50°, 60°, 70°, 80°, or 85°, or even 90° with respect to a plane of mounting structure.

In some cases, the plurality of photovoltaic modules is synchronously rotatable. That is, each photovoltaic module rotates at substantially the same time and at substantially the same rate as all other photovoltaic modules. As an alternative, one or more photovoltaic modules can be rotated out of sync (or asynchronously) with respect to at least a remainder of the photovoltaic modules. In some cases, photovoltaic modules are independently rotatable. That is, one photovoltaic module can be rotated independently with respect to another photovoltaic module.

The system can further comprise another mounting structure. The other mounting structure can be coupled to the mounting structure with the aid of posts, such as, for example, vertical posts.

Reference will not be made to the figures, wherein like numerals refer to like parts throughout. It will be appreciated that the figures and structures therein are not necessarily drawn to scale.

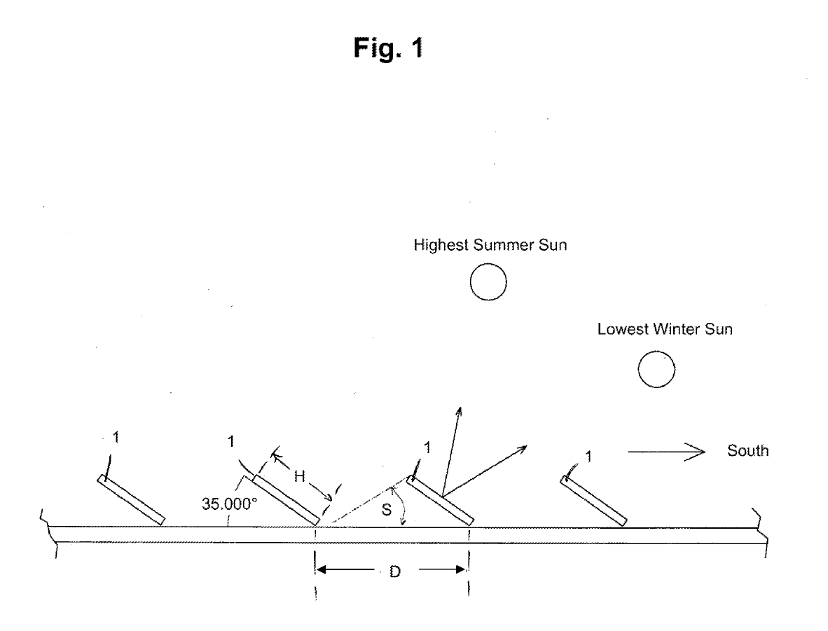

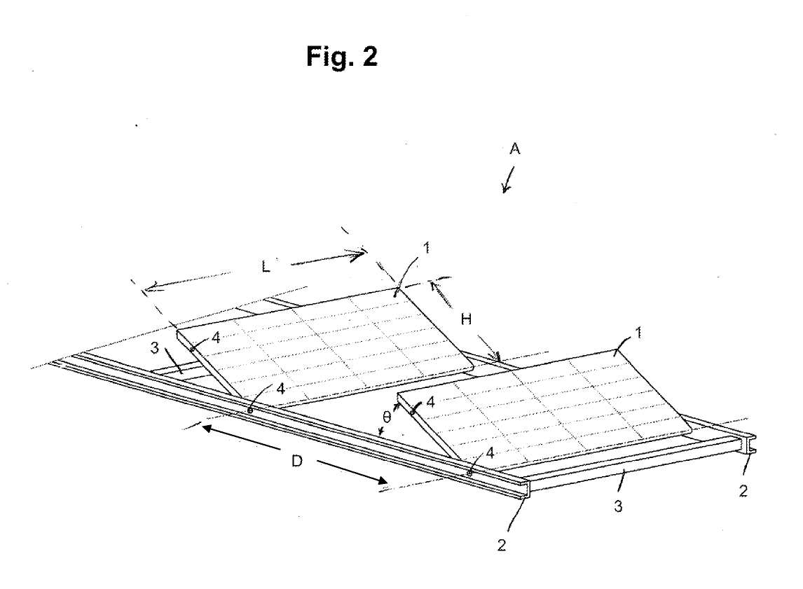

FIG. 2 is a perspective view showing a section of a mounting structure for a part of a solar array. For convenience, this part of the mounting structure will be referred to as substructure A. The modules 1 are mounted in a frame comprising, for example, “C” channels 2 and cross support beams 3. A module can include one or more photovoltaic (solar) cells, which can include a photoactive material that is configured to generated electricity upon exposure to light or select wavelengths of light. Examples of photoactive material include silicon, CdTe, and copper indium gallium diselenide (CIGS). The height H of the solar modules can be smaller than their length L, and they are spaced a distance D apart that is approximately two times H, similar to the mid latitude geometry that was described in FIG. 1. Approximate dimensions may be, for example, 12 inches for H, 48 inches for L, and 24 inches for D. In some examples, modules 1 can include silicon modules of standard construction, but smaller, with a glass top sheet, TPE back sheet, and an aluminum frame. Modules 1 can also be thin film modules of similar construction. Alternatively and preferably, modules 1 can be of a novel module construction that has a molded honeycomb back sheet. Examples of such module constructions, referred to herein as light weight stiff (LWS) modules, are provided, for example, in PCT Publication No. WO/2012/096998 (“PHOTOVOLTAIC MODULES AND MOUNTING SYSTEMS”), filed Jan. 10, 2012, which is entirely incorporated herein by reference. Holes or passages 4 can be provided either in the aluminum frames of the standard construction modules, or through the honeycomb structure of LWS modules. Thin wall light weight metal tubes inserted through holes 4 provide the mounting points to attach the modules to channels 2 and to fix the modules at an angle 0, such as at least about 1°, 2°, 3°, 4°, 5°, 10°, 20°, 30°, 40°, 50°, 60°, 70°, 80°, or 85°, or even 90° with respect to a plane of the substructure A.

Continuing with reference to FIG. 2, the assembly of the frames and modules for substructure A of the array mounting system may be more economically accomplished in the factory, although it can be done at the site in some cases. The length of the structure can be adjusted to match the length of other features of the rest of the mounting structure, or it can span several features within the limits of the structural rigidity. The geometry can be such that the modules can fold flat into the framing for more efficient packing and shipping. Although not specifically shown in the figure, the wiring of the modules can also be done in the factory. Wires from the back of the modules can be fed into the supporting tube at the bottom of the modules and routed through the tube and into channel 2 where they can plug into a pre-molded interconnect cable. Also with respect to this mounting scheme, channels 2 and cross support beams 3 may be constructed from aluminum and may have other cross sectional shapes. For example, the “C” channel may be a box beam or “I” beam, etc. These structures may also be economically molded parts made from suitable polymeric materials like polystyrene, polyethylene, or other resins. The remaining parts of the array mounting system which are described below can likewise be molded parts.

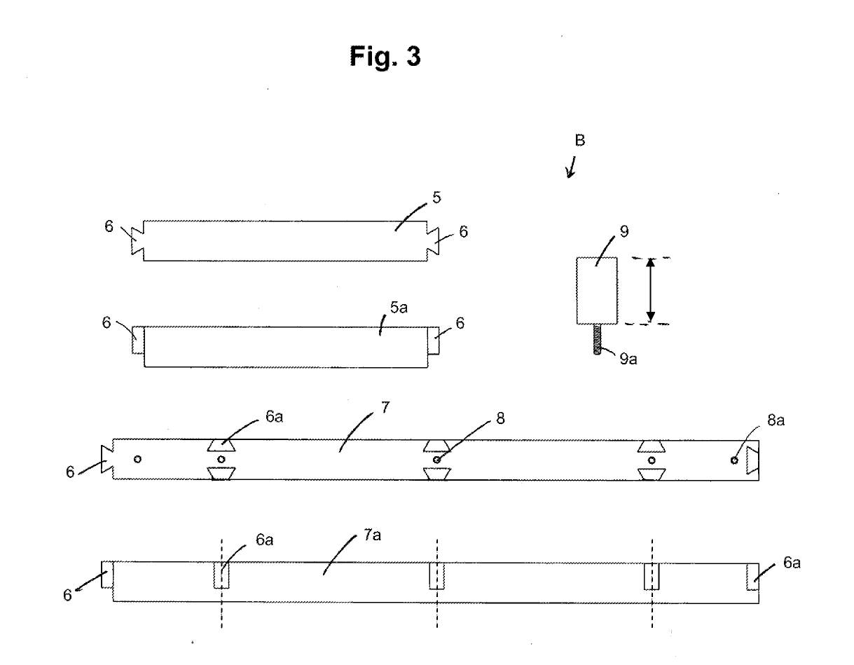

FIG. 3 is an example of individual molded elements of the rest of the module array mounting system in FIG. 2, referred to as substructure B. Substructure B comprises a plurality of modular elements. The modular elements can be snap-in modular elements—i.e., modular elements that are configured to snap into place. In an example, a first element with a male attachment member can snap into a female attachment member of a second element, thereby coupling the first element to the second element. Element 5 is a top view of a cross member with snap in attaching features 6. The member is largely hollow and may contain openings in the top through which sand or other ballast can be added after assembly. Element 5a is a side view of member 5. Note that snap in features 6 do not extend all the way to the bottom of the member. Element 7 is a top view of a longitudinal section of the mounting system. It contains pockets 6a into which snap in features 6 fit. It also has a series of molded threaded holes 8 that may or may not extend through the thickness of the section. In this example, the holes are provided at preselected positions to give equal spacing to an extended assembly. Holes 8a near the ends of element 7 are provided for termination. Element 7a is a side view of element 7 showing that the depth of pockets 6a are matched to the length of features 6. Part 9 is a vertical post (i.e., when mounted, it is oriented along an axis that is orthogonal to the element 7) with approximately the same cross section as elements 5 and 7. The cross section of part 9 need not be square as illustrated—for instance, it could have a round (e.g., circular, oval), rectangular, polygonal or hybrid (e.g., combination of round and rectangular) shape. The part 9 contains a molded screw 9a that fits into the threaded holes 8. The length/of the part may be varied to meet the needs of an individual site. As an example of the scale of a typical system, element 5 may be about 4 feet long, element 7 may be about 8 feet long, and part 9 may be from a few inches to a foot or more long.

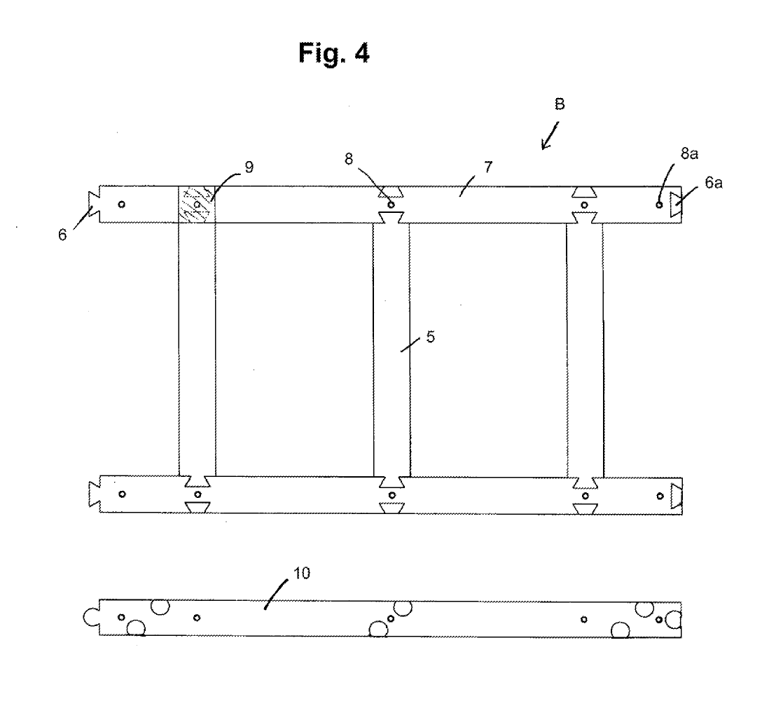

FIG. 4 shows an example of a configuration for interconnecting parts of a substructure B (e.g., the parts of the substructure B described in FIG. 3). Cross members 6 snap into their corresponding features in longitudinal sections 7. Vertical posts 9 (only one shown) then screw into holes 8 at each location of the cross members, and provide a locking feature to hold the snap in areas together. In this example, the cross members are placed on 32-inch centers which is twice that commonly used in house framing; however, this design is not critical to the practice of the invention. Referring still to FIG. 4, an alternative style of interconnect is shown as longitudinal section 10. Here, the angular shape of features 6 and 6a are shown replaced by circular elements of cylindrical shape. The circular elements of cylindrical shape may otherwise be similar in scale, depth, etc., to the features 6, 6a. The protruding elements may be spherical or ball shaped to snap into a ball joint. This may be a useful design for locations that are not uniformly flat. For example, it can enable the structure to conform to undulations in the ground or on a roof.

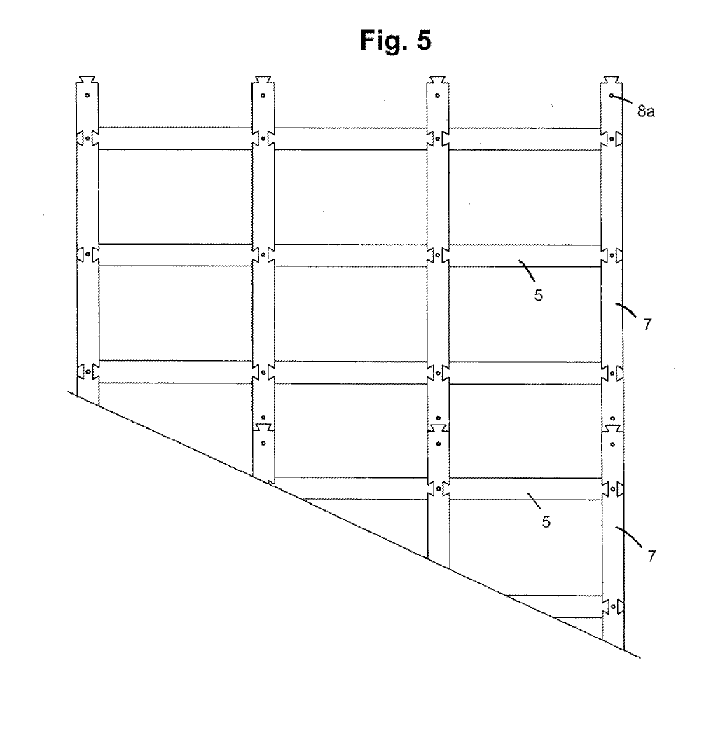

FIG. 5 shows a planar view of a portion of an example interconnected array of substructures B. Vertical posts 9 (not shown) can be present at all of the intersection points of members 5 to help hold the structure together. The vertical posts may be removable. In addition, these posts may be placed at positions 8a where the array terminates. The spacing of the members 5 stays the same across the intersection locations of longitudinal sections 7. As described elsewhere herein, the members 5 may contain extra ballast (like sand, or other weighed objects) if the roof or wind conditions allow or require it.

Photovoltaic Systems

Another aspect of the disclosure provides photovoltaic systems. A solar (or photovoltaic) module array mounting system can comprise a solar (or photovoltaic) module array comprises one or more photovoltaic modules. A photovoltaic module can include one or more photovoltaic cells. An individual photovoltaic cell can be configured to generate electricity upon exposure to electromagnetic energy (or light). The system further comprises a first mounting structure comprising a frame that mounts the solar module array. The first mounting structure permits rotation of an individual photovoltaic module of the one or more photovoltaic modules of the solar module array. The mounting system further comprises a second mounting structure mounted to the first mounting structure with the aid of a plurality of posts. The second mounting structure comprises modular elements that are configured to couple to one another with the aid of snap-in features. In some cases, the modular elements are removable from one another, and can be readily coupled to one another for ease of construction.

The second mounting structure can include one or more molded elements. The one or more molded elements of the second mounting structure can be interconnected, such as with the aid of securing members, such as, for example, snap-fitting features, bolts, welding, wires, or screws.

The second mounting structure can comprise a cross member with a snap-in feature. The cross member can be hollow and can contain one or more openings for adding ballast or other weights. The second mounting structure can further comprise one or more a longitudinal sections, each having a pocket (or groove). The snap-in feature on the cross member can snap into the pocket on the longitudinal section. This can secure the cross member against the longitudinal section. The longitudinal section can further comprise a threaded hole. An individual post of the plurality of posts can be mounted in the threaded hole.

In some examples, the plurality of posts includes vertical posts. The posts can be oriented at an angle of at least about 1°, 2°, 3°, 4°, 5°, 10°, 20°, 30°, 40°, 50°, 60°, 70°, 80°, or 85°, or even 90° , (i.e., vertical) with respect to the second mounting structure. The posts can each provide a locking feature to a frame of the second mounting structure.

The solar module array can include a molded honeycomb back sheet. The back sheet can be as described in Patent Cooperation Treaty (PCT) Publication No. WO/2012/096998 (“PHOTOVOLTAIC MODULES AND MOUNTING SYSTEMS”), filed Jan. 10, 2012, which is entirely incorporated herein by reference.

The solar module array is rotatably mounted to the frame. An individual solar module of the solar module array can be rotatable along an angle from about 0° to 180°. The solar module can be incremented by at least about 0.1°, 1°, 2°, 3°, 4°, 5°, 10°, 20°, 30°, 40°, 50°, 60°, 70°, 80°, or 85° increments.

In some situations, the frame of the first mounting structure includes a channel and a cross support beam. The channel can have various shapes and configurations. In an example, the channel is V-shaped or U-shaped. In some examples, an individual post of the plurality of posts is mounted in the channel.

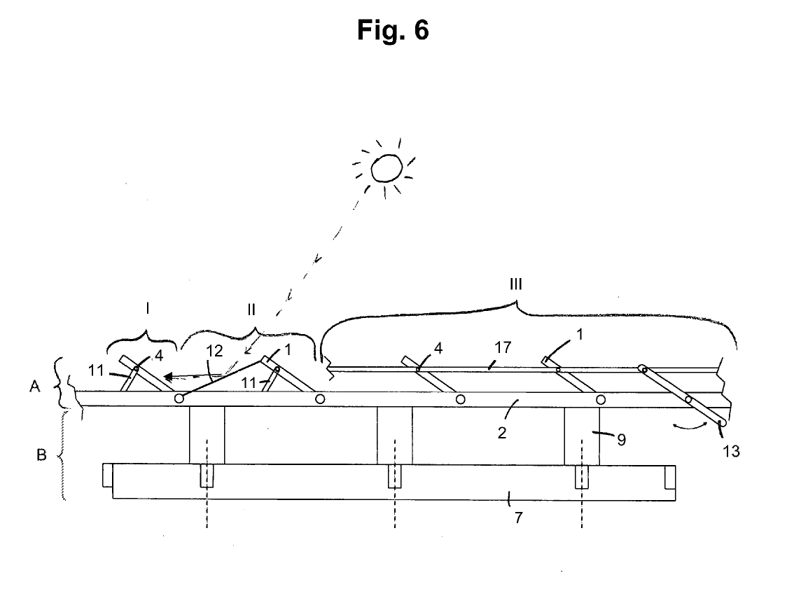

FIG. 6 is a side view of a section of a substructure A and a substructure B after they are joined together using, for example, self tapping screws holding channels 2 to vertical posts 9. The substructure A may be longer than the unit length of the sections of the substructure B that it rests on. The details of other features will be discussed with respect to variations in the system architecture that were not fully explained in the general layout shown in FIG. 2.

FIG. 6 shows various layouts (or configurations) of photovoltaic modules with respect to substructure A. Layout I illustrates a snap-in support 11 attached to the metal tube through hole 4 in the module 1 and affixed to channel 2 of substructure A to hold the module 1 at a angle equal to the latitude of the array. This first layout has relatively low wind loading from a worst case northerly wind because of the short height of the module and the open slots between it and its neighbors, but it suffers from lower collection of sunlight for the higher sun positions.

Layout II is like layout I except that it adds a light weight mirror 12 (or other solar concentrator) for directing much of the sunlight that would otherwise be lost onto the adjacent module. As an alternative, the light weight mirror 12 can be replaced with an optically reflective sheet. The mirror 12 can extend from a first portion (e.g., top) of one photovoltaic module to a base of the support substructure A. Although element 12 is called a mirror, it need not be specular as in the ordinary sense of a reflected image. A white scattering surface can also be effective in bouncing light to the other photovoltaic module. Some additional diffuse light from the sky can also be directed to the adjacent module. Aluminum coated mirrors on various plastic materials, where the mirror coating is applied to the rear surface and is protected by other backside coatings, may also be used, such as, for example, a rear surface protected mirror deposited on acrylic sheet. Acrylic can have preferable weathering characteristics, high stiffness, and is ultraviolet (UV) stable. Its low index of refraction and high transparency across the solar spectrum are well suited for providing high reflection over years of use. The addition of the mirror sheet makes the structure safer against wind loading from almost any direction, since there is a resultant downward wind component acting to hold the array against the roof or ground. The configuration of Layout II can permit light that is not fully incident on one photovoltaic module to be reflected by the mirror 12 (or other optically reflective surface) to an adjacent photovoltaic module.

Still referring to FIG. 6, layout III illustrates a third layout of the mounting structure. The tubes through holes 4 in the modules 1 are inserted and captured, but allowed to rotate in holes in a bar 17. The bar can have a length approximately equal to that of longitudinal section 7, or it can be long enough to connect modules spanning two or more sections. In this layout, the angle of a series of modules may be changed throughout the year as the position of the sun changes. The change in position is schematically indicated by the angular placement of handle 13; however, the actual mechanism can take many forms, including, without limitation, a motorized feedback coupling. The series of modules can be rotated in unison using the handle 13. In some cases, a motor (or other motorized mechanism) can be used as an alternative to the handle. The motor can be coupled to a control system for regulating the motor. For example, the motor can be in mechanical communication with the handle 13. The control system can be in communication with a sensor for measuring wind speed, and another sensor for measuring vibration loading on the modules or any of the mounting structures, such as vibration loading in the presence of wind.

An additional feature of this mounting is the ability to lay the array reasonably flat during periods of high wind, thus reducing the wind loading significantly. This may be accomplished automatically, for example, by using the input of a wind direction and velocity sensor to cause the array to flatten for preselected wind conditions. Since the array of modules can be kept pointed directly at the sun during the year, the energy output can be increased over that gathered from the fixed array of layout I, and the wind loading can be lowered relative to the fixed array of layout I. The sunlight collection efficiency can be lower than for layout II, since some sunlight still falls between modules at higher sun angles even though the array always points directly towards the sun. To increase the sunlight collection efficiency, mirrors similar to 12, but no higher than the module, can be hinged at the tops of the modules and pinned to slide in a slot in channel 2 (this feature is not shown in the figure). These mirrors can adjust as the angle of the modules is changed and still lie approximately flat in high wind conditions. In some cases, this configuration may provide an improved sunlight collection efficiency compared to the layout II. The improved sunlight collection efficiency may be offset by a higher cost of cost of the angle adjustment system and the adjustable mirror system.

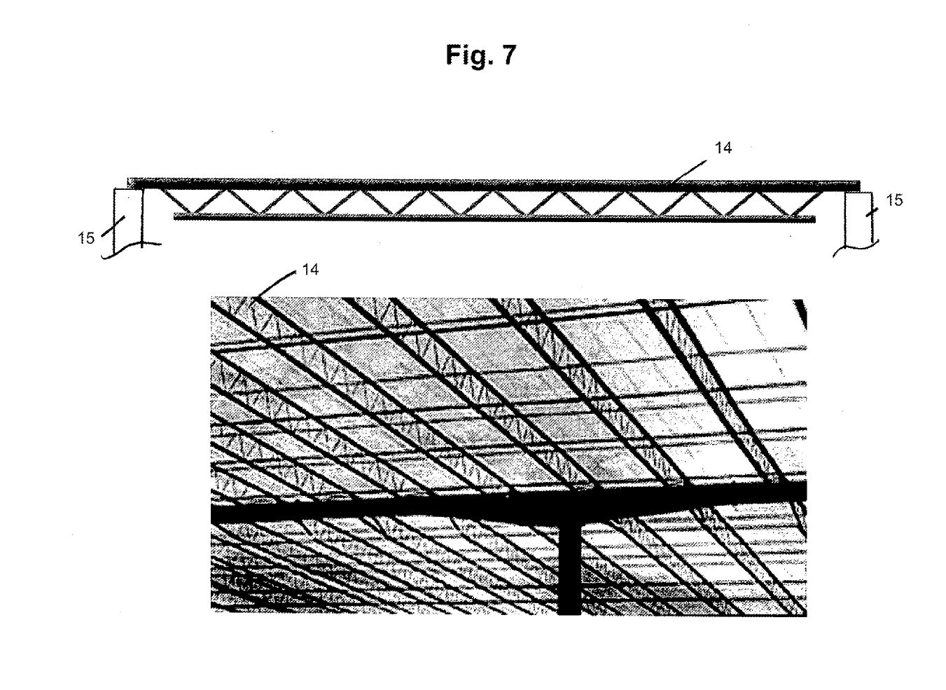

FIG. 7 shows a schematic view of a “Series K” steel joist 14 and a photograph of joists being used in a roof application. In this example, the “K” type joist, which can be used for open spans up to 60 feet, is shown. Similarly constructed but heaver joists can be used for span lengths between 60 and 120 feet. Any other types of joists available or known in the art may be used. A post 15 is shown at each end of the joist 14. The posts are set in the ground and have a height which allows the joist 14 to clear the ground along its length. This construction can be sufficiently close to the ground to permit a worker of normal height to readily step over the joist during and after assembly.

In some examples, the mounting structure of FIG. 7 can be adapted to be mounted on a support surface (e.g., roof) without penetrating the support surface. This can be accomplished with the aid of one or more ballasts or other weight(s). In some examples, weights are included in the joist 14, posts 15, or both. A post 14 or joist 15 can be hollow to accommodate a weight (e.g., ballast). The joist 14 and/or posts 15 can be used in conjunction with various mounting systems provided herein, such as substructures A and B of FIG. 6.

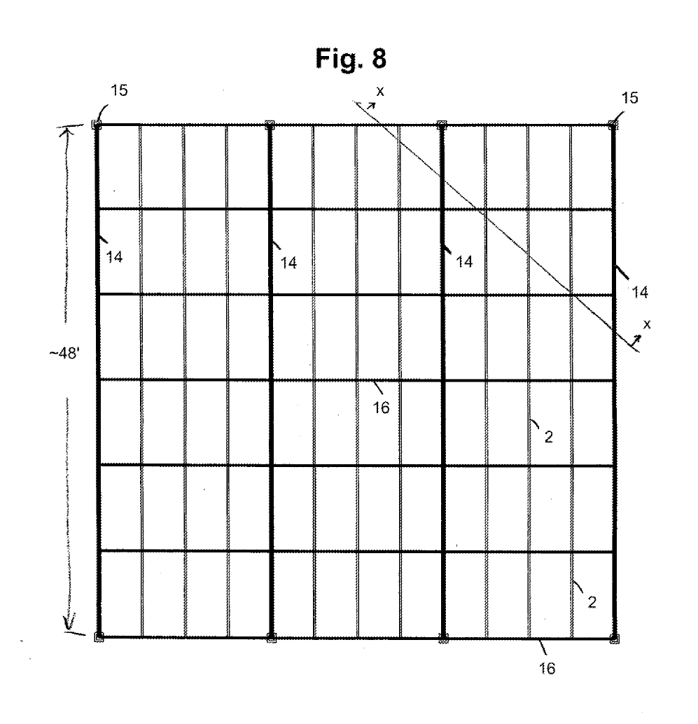

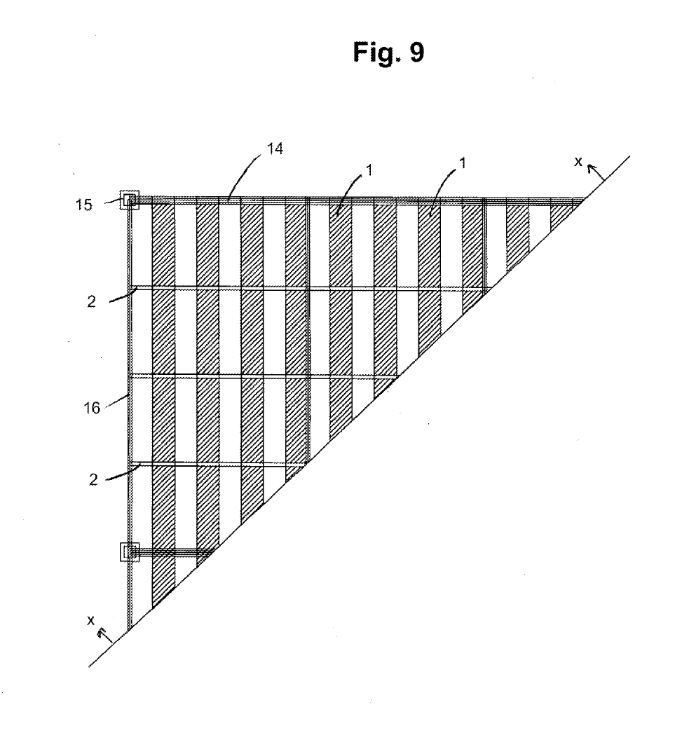

A planar view of a sample ground mounting layout using building construction joists is shown in FIG. 8. Four rows of joists 14 attached to posts 15 outline a square area that may be, for example, about 48 feet on a side. The joists 14 attached to posts 15 provide the major load bearing elements of the array. Cross bracing beams 16 span the distance between the joists and between the posts along each side. These beams may be steel “I” beams or box beams that are much lighter in weight and less rigid than the joists. The module carrying members are attached across beams 16 and can be, for example, the channels 2 described for substructure A in FIG. 2. An expanded view of a section of the array above line x-x is shown in FIG. 9. The hatched areas represent the modules 1 of FIG. 2 and the open regions are the areas between the modules. The open regions provide worker access to all parts of the array both during assembly or later to perform repair and maintenance on the array. If the module layout is similar to, for example, the layout II in FIG. 6, then some of mirror sections 12 may easily be removed or folded out of the way to gain access to a particular location.

While specific examples with respect to module and array sizes have been used to help clarify the description of the invention, module and array sizes are not limited to these dimensions. For example, the elements of the disclosure can be sized to fit very efficiently into standard shipping containers which are approximately 8 feet high, 8 feet wide, and 40 feet long. Internal sizes can be a few inches smaller in each dimension. The joists can be about 39.5 feet long, and the module width can be somewhat wider than 48 inches, allowing a reasonable amount of space around the edges for adequate packing protection. The array layout need not be square. The array layout may have a rectangular (or other) shape depending on optimization parameters. Adjustments in the sizes are readily ascertained to provide various economies for any given situation.

Systems and methods provided herein may be combined with or modified by other systems and methods, such as, for example, systems and methods provided in U.S. Patent Publication No. 2011/0300661 (“SOLAR CELL INTERCONNECTION METHOD USING A FLAT METALLIC MESH”), and PCT Publication No. WO/2012/096998 (“PHOTOVOLTAIC MODULES AND MOUNTING SYSTEMS”), which are entirely incorporated herein by reference.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents. It is intended that the following claims define the scope of the invention and that methods and structures within the scope of these claims and their equivalents be covered thereby.

What is claimed is:

1. A photovoltaic module array mounting system, comprising:
a photovoltaic module array comprising a plurality of photovoltaic modules, wherein an individual photovoltaic module of said plurality comprises one or more photovoltaic cells, each of which is configured to generate electricity upon exposure to light;
a first mounting structure comprising a frame that mounts the photovoltaic module array, wherein the first mounting structure permits rotation of an individual photovoltaic module of said plurality of photovoltaic modules of said photovoltaic module array; and
a second mounting structure mounted to the first mounting structure with the aid of a plurality of posts, wherein said second mounting structure comprises modular elements that are configured to couple to one another with the aid of snap-in features.

2. (canceled)

3. (canceled)

4. The mounting system of claim 1, wherein the second mounting structure comprises a cross member with a snap-in feature.

5. The mounting system of claim 4, wherein the cross member is hollow and contains one or more openings for adding ballast.

6. The mounting system of claim 4, wherein the second mounting structure further comprises a longitudinal section with a pocket.

7. The mounting system of claim 6, wherein the snap-in feature on the cross member snaps into the pocket on the longitudinal section.

8. The mounting system of claim 6, wherein the longitudinal section further comprises a threaded hole.

9. The mounting system of claim 8, wherein an individual post of said plurality of posts is mounted in the threaded hole.

10. (canceled)

11. The mounting system of claim 1, wherein the posts each provide a locking feature to a frame of the second mounting structure.

12. The mounting system of claim 1, wherein the photovoltaic module array includes a molded honeycomb back sheet.

13. (canceled)

14. The mounting system of claim 1, wherein the frame of the first mounting structure includes a channel and a cross support beam.

15. The mounting system of claim 14, wherein an individual post of said plurality of posts is mounted to said channel.

16. A system for supporting a photovoltaic module array, comprising:
a photovoltaic module array comprising a plurality of photovoltaic modules, wherein an individual module of said plurality of photovoltaic modules comprises one or more photovoltaic cells for generating electricity upon exposure to electromagnetic radiation; and
a mounting structure disposed adjacent to said photovoltaic module array, wherein said mounting structure comprises a frame, wherein said mounting structure supports said plurality of photovoltaic modules at a given angle with respect to the mounting structure, wherein an individual photovoltaic module of said plurality of photovoltaic modules is rotatably mounted to the mounting structure and is held in position by a support member mounted to the individual photovoltaic module and a channel in the mounting structure, and wherein at least two individual photovoltaic modules of said plurality of photovoltaic modules are adapted to fold flat into the mounting structure.

17. The system of claim 16, wherein said at least two individual photovoltaic modules are adapted to rest parallel to the mounting structure without overlapping one another.

18. The system of claim 16, further comprising an optically reflective structure mounted to the mounting structure and in-between said at least two individual photovoltaic modules, wherein said optically reflective structure directs at least a portion of incident electromagnetic radiation onto one said at least two individual photovoltaic modules.

19. The system of claim 18, wherein said optically reflective structure is a mirror.

20. (canceled)

21. The system of claim 16, wherein said plurality of photovoltaic modules are synchronously rotatable.

22. The system of claim 16, further comprising another mounting structure, wherein said another mounting structure is coupled to said mounting structure with the aid of posts.

23. The system of claim 22, wherein said posts are vertical posts.

24. The system of claim 16, wherein the mounting structure comprises:
a plurality of joists for holding the photovoltaic module array; and
a plurality of posts for holding the joists.

25. The system of claim 24, wherein the mounting structure is used for roof mounting system or ground mounting.
